(19) United States
(12) Patent Application Publication
(10) Pub. No.: US 2010/0122728 A1
(43) Pub. Date: May 20, 2010

(54) Photovoltaic device using low iron high transmission glass with antimony and reduced alkali content and corresponding method

(76) Inventors: Kevin R. Fulton, Howell, MI (US); Richard Hulme, Rochester Hills, MI (US); Scott V. Thomsen, South Lyon, MI (US)

Correspondence Address: NIXON & VANDERHYE, PC, 901 NORTH GLEBE ROAD, 11TH FLOOR, ARLINGTON, VA, 22203, US

(21) Appl. No.: 12/292,346

(22) Filed: Nov. 17, 2008

(51) Int. Cl. H01L 31/00; C03C 3/095; C03C 3/087; C03B 13/08

(52) U.S. Cl. 136/256; 501/64; 501/70; 65/94

(57) ABSTRACT

A high transmission low iron glass includes antimony, has reduced total alkali content, and increased silica content, and is suitable for use in photovoltaic devices (e.g., solar cells) or the like. A method of making the glass is also provided. In certain example embodiments, the glass composition may be made on a pattern line with a highly positive batch redox.

This invention relates to a high transmission low iron glass that includes antimony, has reduced total alkali content, and increased silica content, for use in photovoltaic devices (e.g., solar cells) or the like. A method of making the glass is also provided. In certain example embodiments, the glass composition may be made on a pattern line with a highly positive batch redox. The glass, generally speaking, is a low density/lower reflective loss glass.

### BACKGROUND AND SUMMARY OF EXAMPLE EMBODIMENTS OF THE INVENTION

Solar cells are known in the art. A solar cell may include, for example, a photoelectric transfer film made up of one or more layers located between a pair of substrate. These layers may be supported by a glass substrate. Example solar cells are disclosed in U.S. Pat. Nos. 4,510,344, 4,806,436, 6,506,622, 5,977,477, and JP 07-122764, the disclosures of which are hereby incorporated herein by reference.

Substrate(s), sometimes called superstrate(s), in a solar cell are sometimes made of glass. Glass that is fairly clear in color and highly transmissive to visible light is sometimes desirable. Glass raw materials (e.g., silica sand, soda ash, dolomite, and/or limestone) typically include certain impurities such as iron, which is a colorant. The total amount of iron present is expressed herein in terms of Fe₂O₃ in accordance with standard practice. However, typically, not all iron is in the from of Fe₂O₃. Instead, iron is usually present in both the ferrous state (Fe²⁺; expressed herein as FeO, even though all ferrous state iron in the glass may not be in the form of FeO) and the ferric state (Fe³⁺). Iron in the ferrous state (Fe²⁺; FeO) is a blue-green colorant, while iron in the ferric state (Fe³⁺) is a yellow-green colorant. The blue-green colorant of ferrous iron (Fe²⁺; FeO) is of particular concern when seeking to achieve a fairly clear or neutral colored glass, since as a strong colorant it introduces significant color into the glass. While iron in the ferric state (Fe³⁺) is also a colorant, it is of less concern when seeking to achieve a glass fairly clear in color since iron in the ferric state tends to be weaker as a colorant than its ferrous state counterpart.

It has been found that the use of a low-iron highly transparent (optionally patterned) glass is advantageous for solar cell applications. The use of the low-iron composition in combination with the patterned surface(s) of the glass substrate(s) has been found to be advantageous with respect to optical properties, thereby leading to increased solar efficiency of a photovoltaic device such as a solar cell.

In certain example embodiments of this invention, a solar cell glass substrate has a visible transmission of at least 75% (more preferably at least 80%, even more preferably at least 85%, and most preferably at least about 90%). In making such a glass, a batch therefor includes a base glass (e.g., soda lime silica glass) and in addition comprises (or consists essentially of in certain other embodiments) a very small amount of total iron.

In the past some have tried to use cerium oxide in glass for solar cell applications as an oxidizer. However, it has been found that the use of significant amounts of cerium oxide in solar cell glass can result in a loss of solar transmission after ultraviolet (UV) exposure, which is undesirable. Thus, in certain example embodiments of this invention, the use of cerium oxide is substantially avoided.

A known glass (it is unclear whether this glass is “prior art” under U.S. law because it is a Pilkington UK glass presumably made in Europe) is as follows:

| Ingredient | wt. % |
|---|---|
| SiO₂ | 73.22% |
| Al₂O₃ | 1.61% |
| Na₂O | 13.88% |
| CaO | 10.58% |
| MgO | 0.08% |
| SO₃ | 0.356% |
| K₂O | 0.04% |
| total iron (expressed as Fe₂O₃) | 0.022% |
| antimony oxide | 0.20%. |

However, the above-listed Pilkington UK glass has a fairly high total alkali content of 24.58, and therefore has a high density and not as high of a solar transmission as would be desired. It is noted that higher density results in higher solar absorption, and reduced solar transmission.

In this respect, it has surprisingly been found that the use of antimony (e.g., in the form of an oxide of antimony (Sb)) in combination with rather high silica content and low total alkali content in a high transmission low-iron glass for photovoltaic devices (e.g., solar cells) or the like results in a low density glass that need not suffer from the aforesaid problems. Accordingly in certain example embodiments of this invention, antimony (Sb) is provided in low-iron high transmission glass which has increased silica (SiO₂) content and reduced total alkali content. Thus, the resulting glass has a low density (and thus increased solar transmission) and may be substantially free of cerium oxide so as to realize good stability of solar performance (e.g., no or reduced loss of total solar transmission after UV or sunlight exposure).

In certain example embodiments, the patterned glass substrate may have fairly clear color that may be slightly yellowish (a positive b* value is indicative of yellowish color). For example, in certain example embodiments, the patterned glass substrate may be characterized by a visible transmission of at least 90%, a total solar/energy value of at least 90%, a transmissive a* color value of from −1.0 to +1.0 (more preferably from −0.5 to +0.5, and most preferably from −0.2 to 0), and a transmissive b* color value of from 0 to +1.5 (more preferably from +0.1 to +1.0, and most preferably from +0.2 to +0.7). These properties may be realized at an example non-limiting reference glass thickness of from about 3-4 mm.

In certain example embodiments of this invention, in combination with the use of antimony (Sb), high silica content and low alkali content, the glass has no more than 0.07% cerium oxide, more preferably no more than 0.06%, even more preferably no more than 0.04% cerium oxide, even more preferably no more than 0.02% cerium oxide, and possibly 0 or 0.01% cerium oxide.

In certain example embodiments of this invention, there is provided a photovoltaic device comprising: a patterned glass substrate, wherein at least one surface of the patterned glass substrate has an average surface roughness of from about 0.1 to 1.5 μm; first and second conductive layers with at least a photoelectric film provided therebetween; wherein the glass substrate is of a composition comprising:

| Ingredient | wt. % |
|---|---|
| SiO₂ | 73-76% |
| Na₂O | 10-20% |
| CaO | 5-15% |
| MgO | 0-3% |
| K₂O | 0-2% |
| total iron (expressed as Fe₂O₃) | 0.01 to 0.03% |
| FeO | 0 to 0.0015% |
| cerium oxide | 0 to 0.07% |
| antimony oxide | 0.1 to 0.4% |
| SO₃ | 0.1 to 0.6% |

wherein total alkali content (Na₂O+CaO+MgO+K₂O) of the glass substrate is no greater than 24.35% (more preferably no greater than 24.25%, even more preferably no greater than 24.0%, and most preferably no greater than 23.5%), the glass substrate has a density of no greater than 2.495 g/cm3 (more preferably no greater than 2.490 or 2.485 g/cm3), a glass redox of no greater than 0.12 (more preferably no greater than 0.10, and even more preferably no greater than 0.08), and wherein the glass substrate has a total solar transmission (ISO 9090 1.5 AM) of at least 90% (more preferably at least 91%, and most preferably at least 91.5%), a transmissive a* color value of −1.0 to +1.0 and a transmissive b* color value of from 0 to +1.5. An example glass reference thickness is about 3.2 mm. The lower the density of the glass, the higher the total solar transmission thereof.

In other example embodiments of this invention, there is provided a glass comprising:

| Ingredient | wt. % |
|---|---|
| SiO₂ | 73-76% |
| Na₂O | 10-20% |
| CaO | 5-15% |
| MgO | 0-3% |
| K₂O | 0-2% |
| total iron (expressed as Fe₂O₃) | 0.01 to 0.03% |
| FeO | 0 to 0.0015% |
| cerium oxide | 0 to 0.07% |
| antimony oxide | 0.1 to 0.4% |
| SO₃ | 0.1 to 0.6% |

wherein total alkali content (Na₂O+CaO+MgO+K₂O) of the glass is no greater than 24.35%, the glass has a density of no greater than 2.495 g/cm3, the glass has a glass redox of no greater than 0.12, and wherein the glass has a total solar transmission (ISO 9090 1.5 AM) of at least 90%.

In still further example embodiments of this invention, there is provided a method of making patterned glass, the method comprising: providing a molten glass batch in a furnace or melter comprising from 67-75% SiO₂, from about 0.01 to 0.06% total iron, and antimony oxide; forwarding a glass ribbon from the furnace or melter to a nip between first and second rollers, at least one of the rollers having patter defined in a surface thereof, wherein the glass ribbon reaches the nip at a temperature of from about 1,900 to 2,400 degrees F.; at the nip, transferring the pattern from the roller(s) to the glass ribbon; the glass ribbon being at a temperature of from about 1,100 to 1,600 degrees F. upon exiting the nip; annealing the glass ribbon at least after the ribbon exits the nip, thereby providing a patterned glass having a visible transmission of at least 90%, from about 0.01 to 0.06% total iron, and from about 0.01 to 1.0% antimony oxide.

### IN THE DRAWINGS

FIG. 1 is a cross sectional view of a solar cell according to an example embodiment of this invention.

### DETAILED DESCRIPTION OF CERTAIN EXAMPLE EMBODIMENTS OF THIS INVENTION

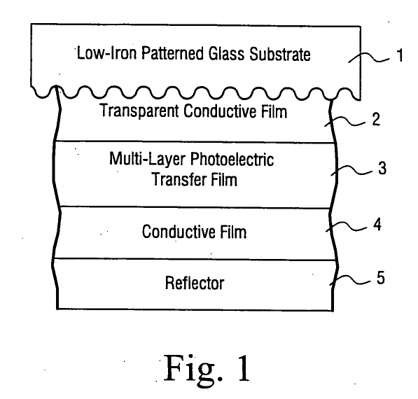

An example solar cell is illustrated in cross section in FIG. 1. The solar cell includes, for example and without limitation, high transmission glass substrate 1, conductive film 2 which may be transparent, a photoelectric transfer film 3 which may include one or more layers, a rear surface electrode 4, and an optional reflector 5. In certain example embodiments, the photoelectric transfer film 3 may include a p-type silicon inclusive layer, an i-type silicon inclusive layer, and an n-type silicon inclusive layer. These silicon inclusive layers may be composed of amorphous silicon or any other suitable type of semiconductor with suitable dopants in certain example embodiments of this invention. The electrodes 2, 4 may be of a transparent conductor such as zinc oxide, or any other suitable material in certain example embodiments of this invention, and the reflector 5 may be of aluminum, silver or the like.

In certain example embodiments of this invention, one or both major surfaces (e.g., the interior surface only) of the glass substrate 1 may be patterned. Light tends to be refracted at interface(s) resulting from the patterning of the glass substrate 1, thereby causing light to proceed through the semiconductor layer(s) at an angle(s) such that the path is longer. As a result, more light can be absorbed by the solar cell and output current and/or efficiency can be improved/increased. In certain example embodiments of this invention, the patterned surface(s) of the glass substrate 1 may have a surface roughness (between peaks/valleys) of from about 0.1 to 1.5 μm, more preferably from about 0.5 to 1.5 μm. In certain example embodiments of this invention, the glass substrate 1 has one or more surfaces which are patterned so as to have a waviness feature defined therein. In the FIG. 1 embodiment, only one surface of the glass substrate 1 is patterned, although in other example embodiments both surfaces of the glass substrate may be patterned.

The optional patterning is preferably defined in the glass substrate 1 during the process of making the glass. An example technique for making such patterned glass is as follows. A furnace or melter is provided, as are first and second opposing rollers which define a nip therebetween. At least one of the rollers has a pattern defined in a surface thereof, where the pattern is made up of a plurality of peaks and valleys. A ribbon of glass exiting the furnace or melter is fed into the nip between the patterning rollers and reaches the nip at a temperature of from about 1,900 to 2,400 degrees F. At the nip, the pattern(s) from the roller(s) is transferred to the ribbon of glass, and then the patterned glass ribbon exits the nip at a temperature of from about 1,100 to 1,600 degrees F. After leaving the nip, the patterned glass ribbon is annealed, and may then be cut into a plurality of sheets. These glass sheets may or may not be heat treated (e.g., thermally tempered), and may be used in solar cell applications such as shown in FIG. 1. Example techniques for making the patterned glass substrate 1 are illustrated and described in U.S. Pat. Nos. 6,796,146 and/or 6,372,327 (except that different types of patterns are used), the disclosures of which are hereby incorporated herein by reference.

Certain glasses for patterned substrate 1 according to example embodiments of this invention utilize soda-lime-silica flat glass as their base composition/glass. In addition to base composition/glass, a colorant portion may be provided in order to achieve a glass that is fairly clear in color and/or has a high visible transmission.

In certain example embodiments of this invention, low ferric and low ferrous glass is made for use in photovoltaic devices or the like, the glass having higher than usual silica (SiO₂) content and lower total alkali content (Na₂O+CaO+MgO+K₂O) in order to improve solar transmission through the reduction of glass structure absorbance and surface reflection. The glass has a lower density, and thus a higher total solar transmission. Glass based on low iron raw materials having a total iron content from about 0.01 to 0.03%, and is oxidized so as to have from 0 to 0.0015% FeO. During the manufacturing process, the batch redox (different than glass redox) of the batch/melt typically ranges from about +12 to +30, but could be as high as +52 in certain example embodiments. The glass includes antimony (Sb) in order to support the oxidation of the FeO to Fe₂O₃. Also, oxidation may be achieved by operations and chemically with sulfates (salt cake, Epsom, or gypsum) and/or nitrates.

Glass density changes can reduce the solar transmission losses through the reduction of surface reflection due to differences in refractive index between the air and the glass. Maximizing the solar transmission is desirable in photovoltaic device applications, and can be achieved by combining low iron raw materials, oxidizing furnace/batch conditions and a glass formulation that reduces glass density in order to reduce the refractive index thus reducing surface reflection losses. In certain example embodiments of this invention, good transmission can be found in samples having silica (SiO₂) content of from 73-75% and total alkali content (Na₂O+CaO+MgO+K₂O) of no greater than 24.35% (more preferably no greater than 24.25%, even more preferably no greater than 24.0%, and most preferably no greater than 23.5%). The resulting glass density is no greater than 2.490 g/cm3, more preferably no greater than 2.470 g/cm3. An exemplary soda-lime-silica glass according to certain embodiments of this invention, on a weight percentage basis, includes the following basic ingredients:

TABLE 1
EXAMPLE GLASS

| Ingredient | Preferred wt. % | More Preferred % | Most Preferred % |
|---|---|---|---|
| SiO₂ | 73-76% | 73-75% | 73.5-74.75 |
| Na₂O | 10-20% | 12-15% | 12.75-14% |
| CaO | 5-15% | 8-12% | 9-11% |
| MgO | 0-3% | 0-1% | 0% |
| K₂O | 0-2% | 0-1% | 0-0.1% |
| Al₂O₃ | 0-5% | 0.5-3% | 1-2% |
| MnO | 0-1% | 0-0.01% | 0-0.005% |
| Cr₂O₃ | 0-1% | 0.0001-0.05% | 0.0001-0.005% |
| total iron (as Fe₂O₃) | 0.01-0.03% | 0.01-0.025% | 0.015-0.022% |
| FeO | 0-0.0015% | 0-0.0010 | 0-0.0005 |
| cerium oxide | 0-0.07% | 0-0.03% | 0% |
| antimony oxide | 0.1-0.4% | 0.15-0.30% | 0.18-0.28% |
| SO₃ | 0.1-0.6% | 0.15-0.5% | 0.25-0.47 |
| (Na₂O + CaO + MgO + K₂O) | <=24.35% | <=24.25% | <=24 or 23.5 |
| glass density (g/cm3) | <=2.495 | <=2.490 | <=2.485 |
| glass redox (FeO/total iron) | <=0.12 | <=0.10 | <=0.08 |

The glass may comprise or consist essentially of the elements listed above in alternative example embodiments of this invention. An example glass reference thickness is about 3.2 mm. The lower the density of the glass, the higher the total solar transmission thereof. In particular, the lower refractive index of the glass arising from the lower density increases transmission in this respect. The glass desirably has low density/lower reflection loss. Other minor ingredients, including various conventional refining aids, such as carbon and the like, or titanium oxide, may also be included in the glass. In certain embodiments, for example, glass herein may be made from batch raw materials silica sand, soda ash, dolomite, limestone, with the use of sulfate salts such as salt cake (Na2SO4) and/or Epsom salt (MgSO4×7H2O) and/or gypsum (e.g., about a 1:1 combination of any) as refining agents.

In certain example embodiments of this invention, the resulting glass has visible transmission of at least 75%, more preferably at least 80%, even more preferably of at least 85%, and most preferably of at least about 90% (sometimes at least 91%) (Lt D65). In certain example non-limiting instances, such high transmissions may be achieved at a reference glass thickness of about 3 to 4 mm (e.g., 3.2 mm).

In certain example embodiments, the antimony may be added to the glass batch in the form of one or more of Sb₂O₃ and/or NaSbO₃. Note also Sb(Sb₂O₅). The use of the term antimony oxide herein means antimony in any possible oxidation state, and is not intended to be limiting to any particular stoichiometry.

In certain preferred embodiments, there is no cerium oxide in the glass. In particular, the presence of cerium oxide can have a detrimental effect on the transmission of the glass after exposure to UV and/or sunlight. This has been seen at 0.01 and 0.02% by weight. Thus, in certain example embodiments, the glass contains no cerium oxide. In certain embodiments, the resulting glass may contain from 0 to 0.01% by weight of cerium oxide. The glass is also free or substantially free of nickel in certain example embodiments of this invention. In certain example embodiments, the glass is free or substantially free of zirconium oxide and/or zinc oxide.

The low glass redox evidences the highly oxidized nature of the glass. Due to the antimony (Sb), the glass is oxidized to a very low ferrous content (% FeO) by combinational oxidation with antimony in the form of antimony trioxide (Sb₂O₃), sodium antimonite (NaSbO₃), sodium pyroantimonate (Sb(Sb₂O₅)), sodium or potassium nitrate and/or sodium sulfate. In certain example embodiments, the composition of the glass substrate 1 includes at least twice as much antimony oxide as total iron oxide, by weight, more preferably at least about three times as much, and most preferably at least about four or eight times as much antimony oxide as total iron oxide.

In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material.

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

The use of antimony (e.g., in the form of antimony oxide) as an oxidizer in the glass batch acts as a decolorizer since during melting of the glass batch it causes iron in the ferrous state (Fe²⁺; FeO) to oxidize to the ferric state (Fe³⁺). This role of antimony as an oxidizer decreases the amount of ferrous state iron left in the resulting glass. The presence of antimony oxide in the glass batch causes an amount of the strong blue-green colorant of ferrous iron (Fe²⁺; FeO) to oxidize into the weaker yellow-green ferric iron colorant (Fe³⁺) during the glass melt (note: some ferrous state iron will usually remain in the resulting glass). The aforesaid oxidation of the iron tends to reduce coloration of the glass and also causes visible transmission to increase. Any yellowish color caused by oxidation of iron into ferric state (Fe³⁺) iron (i.e., positive b*) is acceptable in solar cell applications and need not be compensated for by addition of other colorants thereby saving cost in certain example embodiments of this invention.

It will be appreciated by those skilled in the art that the addition of antimony oxide results in a glass with a lower “glass redox” value (i.e., less iron in the ferrous state FeO). In this regard, the proportion of the total iron in the ferrous state (FeO) is used to determine the redox state of the glass, and redox is expressed as the ratio FeO/Fe₂O₃, which is the weight percentage (%) of iron in the ferrous state (FeO) divided by the weight percentage (%) of total iron (expressed as Fe₂O₃) in the resulting glass. Due to at least the presence of the antimony oxide, the glass redox of glass according to certain example embodiments of this invention is very low as mentioned above, and the amount of iron in the ferrous state (FeO) will also be low as discussed above.

In view of the above, glasses according to certain example embodiments of this invention achieve a neutral or substantially clear color and/or high visible transmission, although there may be a slight yellow color in certain instances. In certain embodiments, resulting glasses according to certain example embodiments of this invention may be characterized by one or more of the following transmissive optical or color characteristics when measured at a thickness of from about 1 mm-6 mm (most preferably a thickness of about 3-4 mm; this is a non-limiting thickness used for purposes of reference only) (Lta is visible transmission %). It is noted that in the table below the a* and b* color values are determined per Ill. D65, 10 degree Obs.

TABLE 2
GLASS CHARACTERISTICS OF EXAMPLE EMBODIMENTS

| Characteristic | General | More Preferred | Most Preferred |
|---|---|---|---|
| Lta (Lt D65): | >=85% | >=90% | >=91% |
| %τe (ISO 9050): | >=90% | >=91% | >=91.5% |
| % FeO (wt. %): | <=0.004% | <=0.003% | <=0.0010% |
| L* (Ill. D65, 10 deg.): | 90-99 | n/a | n/a |
| a* (Ill. D65, 10 deg.): | −1.0 to +1.0 | −0.5 to +0.5 | −0.2 to 0.0 |
| b* (Ill. D65, 10 deg.): | 0 to +1.5 | +0.1 to +1.0 | +0.2 to +0.7 |

The aforesaid characteristics of the glass substrate 1 are for the glass substrate alone, not the overall solar cell or solar cell module.

As can be seen from Table 2 above, glasses for substrate 1 of certain embodiments of this invention achieve desired features of fairly clear color and/or high visible and total solar transmission, with slightly positive b* color in certain embodiments, while not requiring iron to be eliminated from the glass composition. This may be achieved through the provision of the unique material combinations described herein.

### EXAMPLES 1-3

Example glasses for substrates 1 were made according to example embodiments of this invention. Glasses of this invention may be made from batch ingredients using well known glass melting and refining techniques, unless otherwise indicated. The compositions of the glasses according to the examples are set forth below. All amounts of ingredients are in terms of weight percentage.

TABLE 3
EXAMPLES

| Ingredient | Example 1 | Example 2 | Example 3 |
|---|---|---|---|
| SiO₂ | 73.71% | 74.96% | 74.59% |
| Na₂O | 13.53% | 13.07% | 13.17% |
| CaO | 10.65% | 9.97% | 10.23% |
| MgO | 0% | 0% | 0% |
| K₂O | 0.03% | 0.03% | 0.02% |
| Al₂O₃ | 1.42% | 1.40% | 1.36% |
| MnO | 0.0014% | 0.0017% | 0.003% |
| BaO | 0.009% | 0.0094% | 0.0081% |
| Cr₂O₃ | 0.001% | 0.00115% | 0.001% |
| TiO₂ | 0.0105% | 0.0110% | 0% |
| total iron (as Fe₂O₃) | 0.0205% | 0.0205% | 0.015% |
| cerium oxide | 0% | 0% | 0% |
| antimony oxide | 0.252% | 0.245% | 0.2385% |
| SO₃ | 0.383% | 0.280% | 0.383% |
| (Na₂O + CaO + MgO + K₂O) | 24.21% | 23.07% | 23.42% |
| glass density (g/cm3) | 2.492 | 2.477 | 2.481 |
| %τe (ISO 9050): | 91.68% | 91.71% | 92.02% |

Solar characteristics, including total solar transmission and density are also set forth in the table above. It can be seen that the glasses of these examples had rather low densities, and thus had high solar transmission values which are desirable for photovoltaic applications. The samples were about 3.2 mm thick.

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe⁺²) is reported herein as FeO, even though all ferrous state iron in the glass batch or glass may not be in the form of FeO. As mentioned above, iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color. Deep oxidation in certain example embodiments of this invention may be achieved by operations adjustments and chemically by introduction of sulfates in the form of one or more of Sb, salt cake (e.g., Na₂SO₄), Epsom salt (e.g., MgSO₄×7H₂O) and/or gypsum in significant amounts and combination of one or more of these with potassium and/or sodium nitrate. The salt cake may be referred to in the final glass as SO₃. The high amounts of salt cake used in certain example embodiments, can be seen from the large amounts of SO₃ mentioned herein with respect to the final glass composition. In particular, one or more of these oxidizing elements are added to the glass batch in amount(s) sufficient to cause the glass batch to realize a batch redox of from about +12 to +52 in certain example embodiments of this invention, more preferably from about +12 to +30 in certain example embodiments of this invention, even more preferably from about +15 to +30, and most preferably from about +20 to +30 in certain example embodiments. It is noted that batch redox is different than glass redox. Batch redox is known in the art as being generally based on the following. Each component of the batch is assigned a redox number, and the batch redox is calculated as the sum total of the same. The batch redox number is calculated before the glass is made, from the batch. A detailed discussion of “batch redox” and how it is determined is provided in The redox number concept and its use by the glass technologist, W. Simpson and D. D. Myers (1977 or 1978), which is incorporated herein by reference. In contrast with batch redox, glass redox is calculated after the glass has been made from spectral data or the like, and is a ratio of % FeO to total iron in the glass. The high batch redox discussed above causes iron in the ferrous state (Fe²⁺; FeO) to oxidize to the ferric state (Fe³⁺) and thus causes an amount of the strong blue-green colorant of ferrous iron (Fe²⁺; FeO) to oxidize into the weaker yellow-green ferric iron colorant (Fe³⁺) during the glass melt (note: some ferrous state iron may remain in the resulting glass). The aforesaid oxidation of the iron tends to reduce coloration of the glass, reduces % FeO, and causes visible transmission, % UV and % TS to increase. Any yellowish color caused by oxidation of iron into ferric state (Fe³⁺) iron (i.e., positive b*) may be acceptable in solar cell applications and need not be compensated for by addition of other colorants thereby saving cost in certain example embodiments of this invention.

It will be appreciated by those skilled in the art that the high batch redox results in a glass with a lower “glass redox” value (i.e., less iron in the ferrous state FeO). In this regard, the proportion of the total iron in the ferrous state (FeO) is used to determine the redox state of the glass, and redox is expressed as the ratio FeO/Fe₂O₃, which is the weight percentage (%) of iron in the ferrous state (FeO) divided by the weight percentage (%) of total iron (expressed as Fe₂O₃) in the resulting glass. Due to at least the presence of the oxidizing agent(s), the glass redox of glass 1 according to certain example embodiments of this invention is very low as mentioned above, and the amount of iron in the ferrous state (FeO) will also be low as discussed above.

Glass is provided herein which may be used in photovoltaic (e.g., solar cell) applications. However, the use of the glass discussed herein is not so limited. Glass described herein may instead or also be used in applications such as windows, shower doors, and the like in certain example embodiments of this invention.

Once given the above disclosure many other features, modifications and improvements will become apparent to the skilled artisan. Such features, modifications and improvements are therefore considered to be a part of this invention, the scope of which is to be determined by the following claims:

What is claimed is:

1. A photovoltaic device comprising:
a patterned glass substrate, wherein at least one surface of the patterned glass substrate has an average surface roughness of from about 0.1 to 1.5 μm;
first and second conductive layers with at least a photoelectric film provided therebetween;
wherein the glass substrate is of a composition comprising:

| Ingredient | wt. % |
|---|---|
| SiO₂ | 73-76% |
| Na₂O | 10-20% |
| CaO | 5-15% |
| MgO | 0-3% |
| K₂O | 0-2% |
| total iron (expressed as Fe₂O₃) | 0.01 to 0.03% |
| FeO | 0 to 0.0015% |
| cerium oxide | 0 to 0.07% |
| antimony oxide | 0.1 to 0.4% |
| SO₃ | 0.1 to 0.6% |

wherein total alkali content (Na₂O+CaO+MgO+K₂O) of the glass substrate is no greater than 24.35%, the glass substrate has a density of no greater than 2.495 g/cm3 and a glass redox of no greater than 0.12, and wherein the glass substrate has a total solar transmission (ISO 9090 1.5 AM) of at least 90%, a transmissive a* color value of −1.0 to +1.0 and a transmissive b* color value of from 0 to +1.5.

2. The photovoltaic device of claim 1, wherein the glass substrate has a total alkali content of no greater than 24.25%, and comprises:

| | |
|---|---|
| total iron (expressed as Fe₂O₃) | 0.01 to 0.025% |
| cerium oxide | 0 to 0.03% |
| antimony oxide | 0.15 to 0.30%. |

3. The photovoltaic device of claim 1, wherein the glass substrate comprises:

| | |
|---|---|
| total iron (expressed as Fe₂O₃) | 0.01 to 0.025% |
| cerium oxide | 0% |
| antimony oxide | 0.18 to 0.28%. |

4. The photovoltaic device of claim 1, wherein the glass substrate has a total solar (τe) transmission of at least 91.5%, and a density of no greater than 2.490 g/cm3.

5. The photovoltaic device of claim 1, wherein the glass substrate has a positive b* color value.

6. The photovoltaic device of claim 1, wherein the glass substrate has a glass redox value (FeO/Fe₂O₃) no greater than 0.08.

7. The photovoltaic device of claim 1, wherein the glass substrate comprises from 0 to 0.0005% FeO.

8. The photovoltaic device of claim 1, wherein the glass substrate is substantially free of two or more of erbium oxide, nickel oxide, cobalt oxide, neodymium oxide, chromium oxide, cerium oxide and selenium.

9. The photovoltaic device of claim 1, wherein the glass substrate is substantially free of each of erbium oxide, nickel oxide, cerium oxide, cobalt oxide, neodymium oxide, zirconium oxide, zinc oxide and selenium.

10. The photovoltaic device of claim 1, wherein the glass substrate is substantially free of erbium oxide, cerium oxide, and nickel oxide.

11. The photovoltaic device of claim 1, wherein at least one surface of the patterned glass substrate is patterned so as to have has a surface roughness of from about 0.5 to 1.5 μm.

12. The photovoltaic device of claim 1, wherein the glass substrate comprises from 0.15 to 0.30% antimony oxide.

13. The photovoltaic device of claim 1, wherein the glass substrate has a transmissive a* color value of −0.5 to +0.5 and a transmissive b* color value of from +0.1 to +1.0.

14. The photovoltaic device of claim 1, wherein the composition of the glass substrate includes at least twice as much antimony oxide as total iron oxide, by weight.

15. Glass comprising:

| Ingredient | wt. % |
|---|---|
| SiO₂ | 73-76% |
| Na₂O | 10-20% |
| CaO | 5-15% |
| MgO | 0-3% |
| K₂O | 0-2% |
| total iron (expressed as Fe₂O₃) | 0.01 to 0.03% |
| FeO | 0 to 0.0015% |
| cerium oxide | 0 to 0.07% |
| antimony oxide | 0.1 to 0.4% |
| SO₃ | 0.1 to 0.6% |

wherein total alkali content (Na₂O+CaO+MgO+K₂O) of the glass is no greater than 24.35%, the glass has a density of no greater than 2.495 g/cm3, the glass has a glass redox of no greater than 0.12, and wherein the glass has a total solar transmission (ISO 9090 1.5 AM) of at least 90%.

16. The glass of claim 15, wherein the glass has a density of no greater than 2.490 g/cm3.

17. The glass of claim 15, wherein the glass has a density of no greater than 2.485 g/cm3.

18. The glass of claim 15, wherein the glass has total alkali content (Na₂O+CaO+MgO+K₂O) of no greater than 24.25%.

19. The glass of claim 15, wherein the glass has total alkali content (Na₂O+CaO+MgO+K₂O) of no greater than 24.0%.

20. The glass of claim 15, wherein the glass comprises:

| | |
|---|---|
| total iron (expressed as Fe₂O₃) | 0.01 to 0.025% |
| cerium oxide | 0 to 0.03% |
| antimony oxide | 0.15 to 0.30%. |

21. The glass of claim 15, wherein the glass has a total solar (τe) transmission of at least 91.5%.

22. The glass of claim 15, wherein the glass is substantially free of each of erbium oxide, nickel oxide, cerium oxide, cobalt oxide, zirconium oxide, zinc oxide, neodymium oxide, and selenium.

23. The glass of claim 15, wherein the glass is substantially free of erbium oxide, cerium oxide, zirconium oxide, zinc oxide, and nickel oxide.

24. A method of making patterned glass, the method comprising:
providing a molten glass batch in a furnace or melter comprising from 73-76% SiO₂, from about 0.01 to 0.03% total iron, and antimony oxide;
causing a batch redox of from about +12 to +52 to occur in the furnace or melter with respect to the glass batch;
forwarding a glass ribbon from the furnace or melter to a nip between first and second rollers, at least one of the rollers having patter defined in a surface thereof, wherein the glass ribbon reaches the nip at a temperature of from about 1,900 to 2,400 degrees F.;
at the nip, transferring the pattern from the roller(s) to the glass ribbon;
the glass ribbon being at a temperature of from about 1,100 to 1,600 degrees F. upon exiting the nip;
annealing the glass ribbon at least after the ribbon exits the nip, thereby providing a patterned glass having a total solar transmission of at least 91%, from about 0.01 to 0.03% total iron, and from about 0.1 to 0.4% antimony oxide.
